(19) United States
(12) Patent Application Publication
(10) Pub. No.: US 2025/0370043 A1
(43) Pub. Date: Dec. 4, 2025

(54) BIST WITH PHASE NOISE MITIGATION FOR MEASURING OSCILLATOR CHARACTERISTICS

(71) Applicant: NXP B.V., Eindhoven (NL)

(72) Inventors: Ulrich Moehlmann, Moisburg (DE); Florian Hirschgaenger, Hamburg (DE)

(21) Appl. No.: 18/640,188

(22) Filed: Apr. 19, 2024

(51) Int. Cl. G01R 31/3187

(52) U.S. Cl. CPC G01R 31/3187

(57) ABSTRACT

A phase locked loop (PLL) includes an oscillator circuit and a built-in self-test (BIST) circuit. The BIST circuit tests the oscillator circuit by providing a set of input signals to the oscillator circuit and averages resulting output signals to generate an average oscillator characteristic. In some embodiments, the input signals are repeatedly sent to the oscillator circuit during a measurement window. The BIST circuit compares the resulting average oscillator characteristic to an oscillator model and determines whether the oscillator circuit is experiencing a failure based on how well the average oscillator characteristic matches the oscillator model.

### BACKGROUND

Phase-locked loop (PLL) circuits and, in many applications, all-digital PLLs (ADPLL), are used in a wide variety of high frequency applications, including, for example, clock generation, clock clean-up circuits, local oscillators for high performance radio communication links, and ultrafast switching frequency synthesizers in vector network analyzers. A PLL generates an output signal with a defined phase and frequency relationship to an input reference signal. The output signal is matched to the phase of the input reference signal by a feedback loop in which the phase difference between the input reference signal and the output signal is determined by a phase detector. The output from the phase detector (indicating phase error) is received by a loop filter. The loop filter in turn provides an output signal to a frequency-controlled oscillator. In an ADPLL, the phase detector outputs a digital signal, the loop filter is a digital loop filter, and the frequency-controlled oscillator is a digitally controlled oscillator (DCO). In some cases, oscillator failures may cause the PLL to leave a lock state, potentially causing erroneous operation of the system.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a system including a BIST circuit and an oscillator circuit in accordance with some embodiments.

FIG. 2 is a block diagram of an ADPLL including a BIST circuit that controls a DCO in accordance with some embodiments.

FIG. 3 is a block diagram of a BIST circuit that controls a DCO of an ADPLL in accordance with some embodiments.

FIG. 4 is a flow diagram of a method of mitigating measurement noise and detecting errors using a BIST and an oscillator circuit in accordance with some embodiments.

### DETAILED DESCRIPTION

In some cases, production testing and field testing of ADPLLs is complex and resource intensive. Typical ADPLL production testing can include functional testing of the analog parts of the circuitry executed using testers external to a system on a chip (SoC) incorporating the ADPLLs. Support blocks on the ADPLL can impact the size of the ADPLL. In addition, it is difficult to conduct testing in the field or by customers incorporating SoCs into their products. In some cases, testing may only be performed at certain times or under certain circumstances. Further, measurement results may be impacted by various noise sources (e.g., frequency noise or phase noise). Additionally, in some cases, partial (e.g., parametric) failures are more difficult to detect and counteract than total failures. It is therefore desirable to provide a built-in self-test (BIST) mechanism that provides a reliable test of an oscillator of a PLL.

A BIST circuit is used to measure oscillator characteristics of an oscillator circuit (e.g., a DCO) to detect whether the oscillator circuit is experiencing a failure (e.g., a parametric failure or a complete failure). Because characteristics received from the oscillator circuit may be subject to noise (e.g., low frequency phase noise), effective resolution of the oscillator characteristics may be limited. Resolution of oscillator characteristics may be improved by increasing a measurement time window during which the oscillator characteristics are detected. However, in some cases, extending measurement time windows may not improve oscillator characteristic measurement results because additional noise is introduced during the additional time.

By averaging results of multiple sets of oscillator characteristics, a BIST circuit may mitigate the effects of noise, resulting in a more accurate characterization of attributes of the oscillator circuit. Further, the BIST may be configurable in that the BIST circuit may test the oscillator circuit under a variety of conditions where various resolutions and results are desired. For example, the BIST circuit may perform a debug test where relatively high resolution and accuracy is desirable, but measurement time is less important. As another example, the BIST circuit may perform a production test where a short measurement time is important but where functional behavior is still verified. As described herein, a BIST circuit may repeatedly send the oscillator circuit control stimuli such that the oscillator circuit is tested during a measurement window. The BIST circuit may average resulting characteristics of the oscillator circuit measured during the measurement window and evaluate whether the oscillator circuit is experiencing an error by comparing the averaged oscillator characteristic to an oscillator model. In some cases, averaging characteristics may reduce or eliminate statistical variation due to noise, increasing measurement accuracy. As a result, the BIST circuit may detect potential errors at the oscillator circuit at a desired resolution within a desired amount of time. In some cases, a desired ratio between a quantity of desired measurements and a desired measurement window is selected, resulting in a desired effective resolution relative to measurement time.

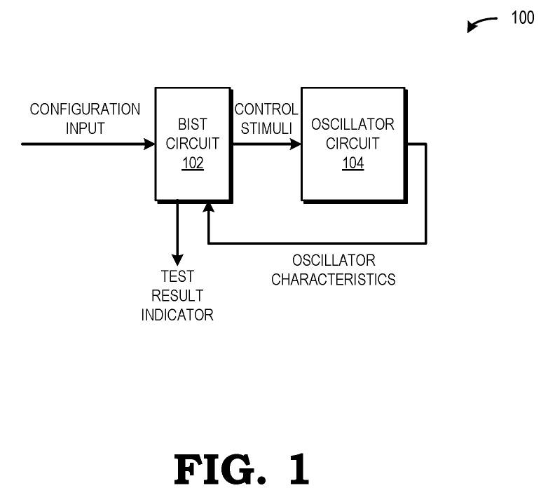

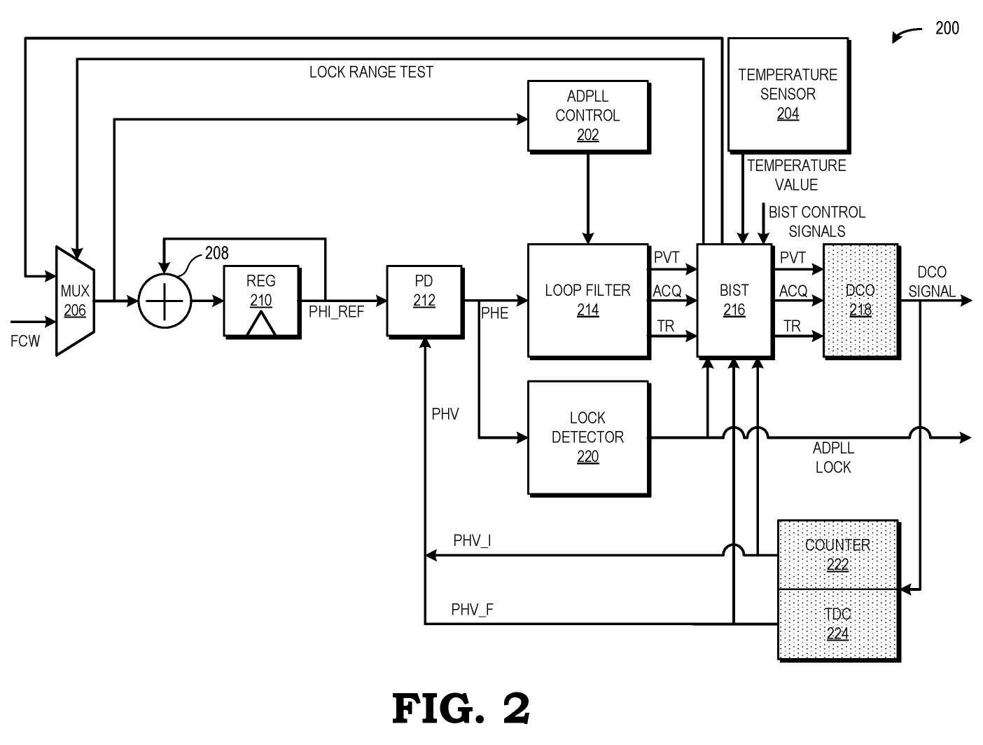

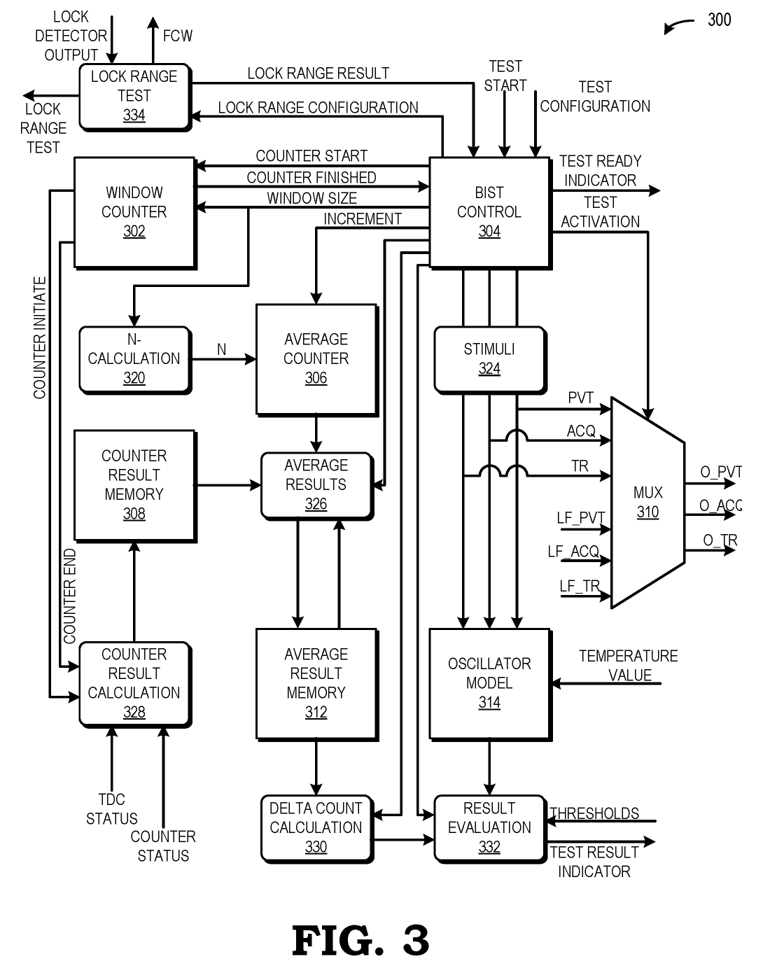

FIG. 1 illustrates a system 100 including an example BIST circuit 102 and oscillator circuit 104 in accordance with some embodiments. In response to configuration inputs, BIST circuit 102 may repeatedly send control stimuli to oscillator circuit 104, causing oscillator circuit 104 to generate output signals under various scenarios set or otherwise simulated in accordance with the control stimuli. The output signals may include oscillator characteristics or oscillator characteristics may be identified or generated based on the output signals. An oscillator characteristic may be a group of numerical values that represent the behavior of the oscillator under a given set of input conditions over time. BIST circuit 102 may average the resulting oscillator characteristics to generate an average oscillator characteristic. As discussed below with reference to FIGS. 2 and 3, the average oscillator characteristic may be compared to an oscillator model to determine whether various portions of the average oscillator characteristic exceed thresholds indicated by the oscillator model. In response to a portion of the average oscillator characteristic exceeding a threshold, BIST circuit 102 may indicate a BIST error as a test result indicator. In response to the average oscillator characteristic not exceeding the threshold, BIST circuit 102 may indicate no BIST error. For example, if none of the averaged numerical values of the average oscillator characteristic exceed respective thresholds indicated by the oscillator model, BIST circuit 102 may indicate no BIST error. In some embodiments, the test result indicator may cause various effects, such as requesting user input or shutting down oscillator circuit 104, BIST circuit 102, or both. In some embodiments, system 100 is a portion of a PLL such as an ADPLL and oscillator circuit 104 is a DCO. In some cases, an average measurement result may be accessed by reading an internal register (e.g., for further detailed analysis or for debug purposes).

The configuration inputs may include a test start signal, test configuration signals, a system temperature, a time-to-digital converter (TDC) status indication, a counter status indication, a current oscillator process-voltage-temperature (PVT) value, acquisition (ACQ) value, or tracking (TR) capacitor bank value, a desired measurement context (e.g., a type of test to be performed) or any combination thereof. The configuration inputs may additionally indicate a size of a measurement window (e.g., by indicating a number of times the control stimuli are to be sent to oscillator circuit 104, by indicating a duration or number of clock cycles during which control stimuli are to be sent to oscillator circuit 104, or both). Further, the configuration inputs may indicate a desired resolution or time constraint. In some cases, the configuration inputs may cause settings of the oscillator circuit (e.g., PVT values, ACQ values, or TR capacitor bank values) to be set in a manner that causes the system to simulate or otherwise test behavior of the oscillator circuit under various operating conditions. As a result, oscillator characteristics generated may be similar to or the same as characteristics generated when the oscillator circuit experiences those operating conditions naturally. Settings changed due to the configuration inputs may be changed prior to generation of oscillator characteristics corresponding to the configuration inputs. BIST circuit 102 may increase a resolution by repeating the measurement of oscillator circuit 104 and averaging the additional results.

In various embodiments, the control stimuli may include one or more PVT values, ACQ values, TR values, or any combination thereof. In some embodiments, the oscillator characteristics are identified or generated based on an oscillator signal output by the oscillator circuit. The oscillator characteristics may be identified or generated by one or more devices (e.g., a counter, a time-to-digital converter (TDC), a loop filter, or any combination thereof) located in a feedback loop between BIST circuit 102 and oscillator circuit 104.

In some cases, the test may be performed for various reasons and parameters of the tests (e.g., resolution, scope of functionality tested, test duration) may differ based on the reasons. As a result, the tests may be performed under various measurement contexts. For example, BIST circuit 102 may regularly perform functional safety (FuSa) tests that are able to detect an error within a certain amount of time (e.g., a detection time) and to react to the error (e.g., by sending an error message or by ramping down an integrated circuit that includes oscillator circuit 104). As another example, BIST circuit 102 may perform a production test of oscillator circuit 104 to check the controllability of each control bit of oscillator circuit 104. In a production test, accuracy of the test may be chosen such that the influence of a control bit is measurable so that its functional behavior is verified. As another example, BIST circuit 102 may perform a characterization test of oscillator circuit 104 to measure features of oscillator circuit 104 such as an amount of mismatch between control bits and whether the amount of mismatch exceeds a threshold. In a characterization test, long measurement times may be acceptable as long as the behavior of oscillator circuit 104 is accurately measured. As another example, BIST circuit 102 may perform a debug test of oscillator circuit 104 where a failure has been previously detected and BIST circuit 102 is used to help locate a source of the failure. In a debug test, long measurement times may be acceptable as long as the behavior of oscillator circuit 104 is accurately measured. Accordingly, a smaller number of output signals may be generated and averaged in response to an indication of a production test as compared to an indication of a debug test. As another example, BIST circuit 102 may perform a calibration test to bias oscillator circuit 104 to a particular frequency (e.g., to reduce settling time of a PLL that includes oscillator circuit 104). In a calibration test, oscillator circuit 104 may be characterized with a high resolution and results may be stored in a memory. In some cases, the calibration test may be performed during boot of oscillator circuit 104 or in response to a boot sequence of oscillator circuit 104. In some cases, the calibration test may be repeated regularly to compensate for parameters such as temperature. In some embodiments, BIST circuit 102 may be read (e.g., via a user interface to external storage equipment or via a register interface to a digital signal processor) during a debug, characterization, or calibration test.

In some cases, the test may be performed at different times, such as during a boot sequence of oscillator circuit 104, in response to a boot sequence of oscillator circuit 104, or while the oscillator circuit 104 is in a standby or idle mode. In some cases, different production tests may be performed depending on when the test is performed. For example, in some embodiments, tests may be performed in response to the boot sequence of oscillator circuit 104. The tests performed in response to the boot sequence may have a longer duration (e.g., due to providing higher resolution or analyzing a larger range of oscillator characteristics, such as a full tuning range), as compared to tests performed while oscillator circuit 104 is in the standby mode. In some embodiments, system 100 being able to initiate tests at different times helps system 100 meet FuSa requirements.

As used herein, a threshold is exceeded whenever a value falls outside of a set of values prescribed by the threshold. For example, if a voltage is to have a value between 2V and 5V, a voltage of 1V would be considered exceeding the threshold of 2V. Similarly, a voltage of 6V would be considered exceeding the threshold of 5V. As another example, a threshold might indicate a voltage less than or equal to 10V. In that case, all voltages greater than 10V exceed the threshold and all voltages less than or equal to 10V do not exceed the threshold.

FIG. 2 illustrates an ADPLL 200 that includes a BIST circuit 216 that controls a DCO 218 and mitigates noise in DCO 218 in accordance with some embodiments. In the illustrated embodiment, ADPLL 200 includes ADPLL control 202, temperature sensor 204, multiplexer 206, adder 208, register 210, phase detector 212, BIST 216, DCO 218, lock detector 220, counter 222, and TDC 224. Components in the ADPLL 200 that are analog are illustrated with shading. Other components in the ADPLL 200 are digital and are illustrated without shading. In some embodiments, BIST 216 corresponds to BIST circuit 102, DCO 218 corresponds to oscillator circuit 104, or both. In various embodiments, some components may be omitted. For example, in some embodiments, ADPLL control 202, temperature sensor 204, lock detector 220, or any combination thereof may be omitted. Further, one of ordinary skill would understand that FIG. 2 illustrates a specific embodiment for clarity purposes and that the teachings of FIG. 2 may be more broadly applied. For example, in some embodiments, ADPLL 200 may be an analog PLL and DCO 218 may be an analog-controlled oscillator circuit.

Multiplexer 206 may select between a functional frequency control word (FCW) signal input that may carry an FCW signal from an external system (e.g., an integer FCW signal or a fractional FCW signal) and an FCW signal input from BIST 216 that may carry an FCW signal received from BIST 216 as part of a lock range test. Adder 208 and register 210 clocked by a reference clock (not shown) may together perform an accumulator function that converts the FCW signal received from multiplexer 206 from the frequency domain to the phase domain and generate a reference phase signal PHI_REF. Register 210 may store a sum of the FCW and existing content, increasing in steps of the FCW. Phase detector 212 compares the reference phase signal PHI_REF with a feedback phase signal PHV derived from the output of DCO 218, and outputs a phase error signal PHE. The feedback signal PHV is generated by combining (e.g., by fixed point concatenation) phase signal outputs from counter 222 and TDC 224. Lock detector 220 indicates, via an ADPLL LOCK signal, whether ADPLL 200 is in a locked state.

Loop filter 214 is controlled by ADPLL control 202 and receives the phase error signal PHE and performs a filtering operation that may filter out unwanted frequency components in the PHE, may define a loop gain, may define a phase margin, or any combination thereof. In some embodiments, the design of loop filter 214 may contribute to settling time, interference suppression, and stability of ADPLL 200. Loop filter 214 provides to BIST 216 three output signals for controlling DCO 218: a process-voltage-temperature control signal PVT, an acquisition control signal ACQ, and a tracking signal TR. As further described below with reference to FIG. 3, when BIST 216 is passing signals from loop filter 214 to DCO 218, each of these signals controls a switched capacitor bank of DCO 218 to vary oscillator characteristics (e.g., output frequency) of DCO 218. Other frequency control mechanisms, such as digital to analog converters with varactors, or a current-controlled oscillator controlled by a current digital-to-analog converter (DAC), are used in alternative arrangements.

Temperature sensor 204 detects a temperature of DCO 218 and sends the temperature to BIST 216. Additionally, in some embodiments, BIST 216 may receive BIST control signals (e.g., start signals, stop signals, a configuration input, etc.), a counter output labeled PHV_I, and a TDC output labeled PHV_F. In some embodiments, BIST 216 may receive the BIST control signals from a user interface, from one or more circuits external to ADPLL 200 or from another circuit of ADPLL (e.g., ADPLL control 202). While ADPLL 200 is in an active mode, BIST 216 passes the output signals from loop filter 214 to DCO 218. As discussed above with reference to FIG. 1, while ADPLL 200 is in a test mode, BIST 216 repeatedly provides a set of input signals (e.g., control stimuli) to DCO 218 based on BIST control signals. Further, BIST 216 may generate an average oscillator characteristic from DCO signals produced by DCO 218 in response to the input signals and compare the average oscillator circuit to an oscillator model (e.g., values of a lookup table (LUT)) to determine whether to issue a BIST error that indicates a failure at DCO 218. In some embodiments, BIST 216 may receive the ADPLL LOCK signal from lock detector 220, which provides information to the BIST regarding whether ADPLL 200 is in lock or not. Further, while in a test mode, BIST 216 may set the FCW of ADPLL 200. Embodiments of BIST 216 may support several test modes (e.g., a DCO test, a TDC/counter test, and a lock test, or any combination thereof). In some cases, as part of a test, the FCW may be set to multiple different values to identify a lock range and lock time of the PLL.

The output from the DCO 218 is received as an input signal at TDC 224. TDC 224 measures and quantizes a timing difference between transitions of the DCO signal from a system clock signal and the transitions in the output from the DCO 218. TDC 224 produces a TDC output labeled PHV_F. Counter 222 accumulates a count of the transitions in the output from DCO 218 and produces an output labeled as PHV_I. As mentioned above, a combination of the signals from TDC 224 and counter 222 results in an input PHV sent to phase detector 212.

FIG. 3 illustrates a BIST circuit 300 that controls an oscillator circuit of an ADPLL and performs a measurement of the oscillator technique that mitigates noise in the resulting measurement in accordance with some embodiments. In the illustrated embodiment, BIST circuit 300 includes window counter 302, BIST control 304, average counter 306, counter result memory 308, multiplexer 310, average result memory 312, and oscillator model 314. In various embodiments, some components or signals may be omitted or additional components or signals may be included. For example, in some embodiments, average counter 306, counter result memory 308, average result memory 312 may be implemented as a single memory. As another example, window counter 302 is not present and only N-calculation 320 is used. As another example, various actions such as N-calculation 320 and average results 326 may be performed by one or more dedicated logic circuits (e.g., a logic circuit dedicated to performing just N-calculation 320 or a logic circuit dedicated to performing N-calculation 320 and average results 326). Although BIST circuit 300 is described herein as being implemented fully in hardware, in some embodiments, portions of BIST circuit 300 are implemented in software.

BIST control 304 may control overall operation of BIST circuit 300. In the illustrated embodiment, BIST control 304 may include processing circuits that perform N-calculation 320, generate stimuli 324, average results 326, evaluate results 332, and lock range test 334. BIST control 304 may receive a test start signal that instructs BIST control to start a test and test configuration signal (e.g., some or all of a configuration input) that provides information regarding a test to be performed (e.g., a target bank, a target portion of a target bank, a desired test resolution/accuracy, a desired measurement context (e.g., a production test, a validation test, a characterization test, a debug test, a calibration test, etc.), a desired measurement window size, a desired tuning range of potential system conditions under which behavior of the oscillator circuit is to be simulated or otherwise tested (e.g., a full tuning range of system conditions or a subset of system conditions), or any combination thereof). Accordingly, in some cases, BIST control 304 may receive a test configuration signal that includes instructions to simulate a full tuning range of system conditions in response to the boot sequence. In those cases, BIST control 304 may identify multiple stimuli to be sent to the oscillator circuit, where the stimuli correspond to multiple points throughout a range of system conditions represented by the full tuning range. In other cases, BIST control 304 may receive a test configuration signal that includes instructions to omit simulating a subset of a full tuning range of system conditions (e.g., a subset corresponding to system conditions that rarely occur) in response to the oscillator circuit entering the standby mode. In those cases, BIST control 304 may identify stimuli corresponding to portions of the full tuning range and may omit sending the identified stimuli to the oscillator circuit. As a result, in some cases, BIST control 304 may perform a more extensive test of the oscillator circuit in response to a boot sequence, as compared to a standby mode. In some embodiments, BIST control 304 may additionally receive parameters such as a desired settling time to achieve a desired thermal and frequency stability margin. Based on the received signals, BIST control 304 calculates a window size and a corresponding N-calculation 320, which indicates a number of times stimuli 324 (e.g., a same set of stimuli repeatedly or a repeated sequence of sets of stimuli) are to be sent to the oscillator circuit. In some embodiments, N-calculation 320 is performed directly. In other embodiments, N-calculation 320 is performed by referencing a memory such as a LUT. In some cases, the number of times stimuli are to be sent to the oscillator circuit is balanced against a window size. Depending on an oscillator noise characteristic, it may be beneficial to average more measurements with a smaller window size or vice versa to get a desired measurement accuracy within a desired measurement time. BIST control 304 indicates the window size to window counter 302 and the result of N-calculation 320 to average counter 306.

In response to receiving the test start signal, the PLL loop is opened to cause multiplexer 310 to replace one or more loop filter LF_PVT/LF_ACQ/LF_TR values from a loop filter such as loop filter 214 of FIG. 2 with one or more PVT/ACQ/TR values generated by BIST control 304 and output oscillator O_PVT/O_ACQ/O_TR values. In some embodiments, BIST control 304 may wait a settling threshold duration to allow a chip temperature to settle. For example, BIST control 304 may wait a settling threshold duration after sending settings to an oscillator (e.g., setting a frequency of the oscillator to a start frequency of a sequence) but before sending a first set of measurement control stimuli to the oscillator circuit. As another example, BIST control 304 may wait the settling threshold duration before sending each set of measurement control stimuli to the oscillator circuit. Allowing the stimuli conditions to settle enable more stable measurement of the oscillator because settling time may enable a frequency of the oscillator to stabilize and mitigate oscillator drift. In some cases, it is beneficial to wait before each measurement because temperature is frequency dependent and vice versa.

Window counter 302 may start measurement in response to a counter start signal. In some embodiments, a status of a counter, a TDC, or both (e.g., a snapshot of a status of counter 222 and TDC 224) are taken because the counter may not be reset during operation of the PLL. In response to an indication of completion of measurement of oscillator characteristics, window counter 302 may perform counter result calculation 328 by calculating a difference between a counter or TDC status at initiation of the measurement with a counter or TDC status at the end of the status. In some implementations, a number of oscillator clock cycles in TDC units may be stored in counter result memory 308. In some embodiments, when a single measurement or a sweep of a bank is accomplished, a result is scaled by dividing by N (the number of measurements) at average results 326 and stored in average result memory 312. In some embodiments, average result memory 312 is accessible to a user. In other embodiments, the result is additionally stored in another memory that is accessible to a user. In some embodiments, if a same set of stimuli are repeatedly sent to the oscillator circuit, the measurements of a same set of stimuli are averaged. In some embodiments, averaging complete sweeps allows for more accurate analysis (e.g., for debug and characterization). However, averaging results of a same set of stimuli may use less hardware effort because only fewer succeeding measurements are stored. BIST control 304 may compare successive control settings to measure oscillator gain in delta count calculation 330.

The resulting delta count may be compared against an oscillator model 314. In various embodiments, the oscillator model may be calculated as an N-order approximation of the oscillator behavior or values matching the model may be stored in a memory such as an LUT. In some embodiments, oscillator model 314 may include temperature drift behavior, process impact, or both. The temperature drift behavior may be compared against a temperature value received from a temperature sensor such as temperature sensor 204. In other embodiments, sensed temperature values are not used at oscillator model 314.

In some embodiments, BIST control 304 compares how well the average oscillator characteristics match the oscillator model to a set of thresholds, which maybe provided as constant values over a range of values of the test (e.g., a total range of values of the oscillator or a subset of values being tested). In response to identifying that the average oscillator characteristic fails to match a portion of the oscillator model indicated as being safe (e.g., by differing from the oscillator model by more than a threshold amount), BIST control 304 may indicate a failure at the oscillator circuit by indicating a BIST error as a test result indicator. In some embodiments (e.g., FuSa tests), the BIST error is indicated by requesting user input asking how to proceed. In other embodiments (e.g., production tests), execution of a test, the oscillator circuit, the BIST circuit is terminated or shut down in response to identifying a failure. Alternatively, in response to identifying that the average oscillator characteristic does not fail to match a portion of the oscillator model indicated as being safe, BIST control 304 may indicate a BIST success as a test result indicator, a counter, delta counter results, or any combination thereof. In other embodiments, BIST control 304 identifies a failure at the oscillator circuit by comparing frequency steps (differences between counter results) to a set of values. In some cases, comparing frequency results provides more stable results and varies less due to process and temperature. In other embodiments, BIST control 304 causes another circuit (e.g., a result evaluation circuit) to perform result evaluation 332 instead of BIST control 304.

As mentioned above, in some cases, BIST control 304 or another circuit (e.g., a lock test circuit) may perform a lock range test 334 that may identify a lock range and lock time of the PLL. BIST control 304 may send or use lock range configuration information to initiate lock range test 334. Lock range test 334 may cause an FCW for the PLL to be specified and a lock range test control signal to be sent, such as by sending the FCW and the lock range test control signal to MUX 206 of FIG. 2. As part of lock range test 334, a lock detector output may be received, such as from lock detector 220. The lock detector output may be used to generate a lock range result which may be sent to or generated by BIST control 304.

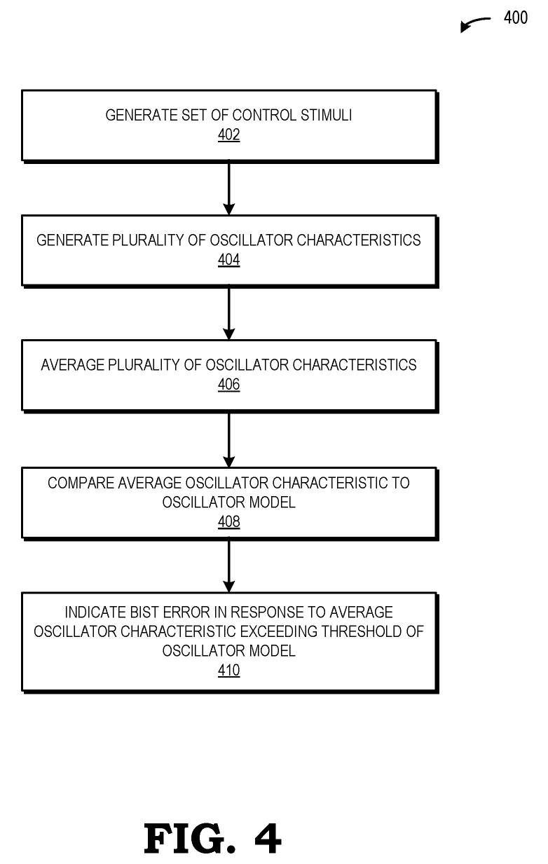

FIG. 4 is a flow diagram of a method 400 of mitigating measurement noise and detecting errors using a BIST and an oscillator circuit in accordance with some embodiments. In some embodiments, various portions are performed in another order or in parallel. For example, in some embodiments, oscillator characteristics are averaged at 406 while other oscillator characteristics are being generated at 404. In some implementations, method 400 is initiated by one or more processors in response to one or more instructions stored by a computer readable storage medium.

At block 402, a set of control stimuli are generated. For example, BIST 216 of FIG. 2 may generate PVT signals, ACQ signals, TR signals, or any combination thereof. At block 404, a plurality of oscillator characteristics are generated in response to the set of control stimuli. For example, DCO 218 may generate a DCO signal in response to the control stimuli.

At block 406, the plurality of oscillator characteristics are averaged. For example, BIST 216 may average the oscillator characteristics into an average oscillator characteristic. At block 408, the average oscillator characteristic is compared to an oscillator model. For example, BIST 216 may compare the calculated average oscillator characteristic to oscillator model 314 of FIG. 3.

At block 410, a BIST error is indicated in response to the average oscillator characteristic exceeding a threshold of the oscillator model. For example, if the average oscillator characteristic differs from the oscillator model by a threshold amount, BIST 216 outputs a BIST error as a test result. Accordingly, a method of mitigating measurement noise and detecting errors is depicted.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disk, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. An all-digital phase-locked loop (ADPLL) circuit comprising:
an oscillator circuit configured to generate an output signal in response to a set of input signals; and
a built-in self-test (BIST) circuit configured to provide the set of input signals to the oscillator circuit based on a configuration input, wherein the configuration input indicates a size of a measurement window during which output signals from the oscillator circuit are averaged to generate an average oscillator characteristic.

2. The ADPLL circuit of claim 1, wherein the BIST circuit is further configured to:
compare the average oscillator characteristic to an oscillator model; and
in response to the average oscillator characteristic failing to match a portion of the oscillator model indicated as being safe, indicate a failure at the oscillator circuit.

3. The ADPLL circuit of claim 2, wherein the average oscillator characteristic failing to match the portion of the oscillator model indicated as being safe comprises at least a portion of the average oscillator characteristic differing from the oscillator model by more than a threshold amount.

4. The ADPLL circuit of claim 2, wherein indicating the failure comprises requesting user input.

5. The ADPLL circuit of claim 2, wherein indicating the failure comprises shutting down the oscillator circuit, the BIST circuit, or both.

6. The ADPLL circuit of claim 1, wherein the BIST circuit is configured to provide the set of input signals to the oscillator circuit in response to a boot sequence of the oscillator circuit.

7. The ADPLL circuit of claim 6, wherein the configuration input includes instructions to simulate a full tuning range of system conditions in response to the boot sequence.

8. The ADPLL circuit of claim 1, wherein the BIST circuit is configured to provide the set of input signals to the oscillator circuit in response to the oscillator circuit entering a standby mode.

9. The ADPLL circuit of claim 8, wherein the configuration input includes instructions to omit simulating a subset of a full tuning range of system conditions in response to the oscillator circuit entering the standby mode.

10. A method, comprising:
generating, at a built-in self-test (BIST) circuit, a set of control stimuli to an oscillator circuit based on a configuration input;
generating, at the oscillator circuit, a plurality of oscillator characteristics based on the set of control stimuli;
averaging, at the BIST, the plurality of oscillator characteristics to generate an average oscillator characteristic; and
comparing the average oscillator characteristic to an oscillator model.

11. The method of claim 10, further comprising indicating a BIST error in response to at least a portion of the plurality of oscillator characteristics exceeding a threshold of the oscillator model.

12. The method of claim 10, wherein generating the set of control stimuli comprises sending the control stimuli to the oscillator circuit repeatedly during a measurement window.

13. The method of claim 10, wherein the set of control stimuli specify one or more process voltage temperature (PVT) values to be set at the oscillator circuit to generate the plurality of oscillator characteristics.

14. The method of claim 10, wherein the set of control stimuli specify one or more acquisition (ACQ) values to be set at the oscillator circuit to generate the plurality of oscillator characteristics.

15. The method of claim 10, wherein the set of control stimuli specify one or more tracking (TR) values to be set at the oscillator circuit to generate the plurality of oscillator characteristics.

16. A system comprising:
an oscillator circuit configured to generate an output signal in response to a set of input signals; and
a built-in self-test (BIST) circuit configured to:
provide the set of input signals to the oscillator circuit based on a configuration input, wherein the configuration input indicates a quantity of output signals from the oscillator circuit to be averaged to generate an average oscillator characteristic; and
determine, based on the average oscillator characteristic and an oscillator model, whether the oscillator circuit is experiencing a failure.

17. The system of claim 16, wherein the oscillator circuit is configured to identify the quantity of output signals based on a measurement context indicated by the configuration input.

18. The system of claim 17, wherein the measurement context is a production test, a characterization test, a debug test, or a calibration test.

19. The system of claim 18, wherein the oscillator circuit is configured to identify a smaller number of output signals to be averaged in response to an indication of a production test as compared to an indication of a debug test.

20. The system of claim 16, wherein the oscillator circuit is configured to wait a settling threshold duration after receiving the configuration input and before providing the set of input signals to the oscillator circuit, wherein the set of input signals comprise measurement control stimuli.
